(19) United States
(12) Patent Application Publication
(10) Pub. No.: US 2008/0257402 A1
(43) Pub. Date: Oct. 23, 2008

(54) Solar Power System with a Number of Photovoltaic Modules

(76) Inventors: Michael Viktor Kamp, Dusseldorf (DE); Thomas Rewig, Lutherstadt Wittenberg (DE); Karl Heinz Diefenbach, Landsberg (DE); Johannes Tibitanzl, Erbshausen (DE)

Correspondence Address: RENNER OTTO BOISSELLE & SKLAR, LLP, 1621 EUCLID AVENUE, NINETEENTH FLOOR, CLEVELAND, OH, 44115, US

(21) Appl. No.: 12/090,358

(22) PCT Filed: Oct. 23, 2006
(86) PCT No.: PCT/EP2006/067681

§ 371 Date: Apr. 16, 2008

(30) Foreign Application Priority Data
Oct. 21, 2005 (DE) 102005050883.9
Oct. 21, 2005 (DE) 102005050884.7

(51) Int. Cl. H01L 31/042

(52) U.S. Cl. 136/251

(57) ABSTRACT

The invention relates to a solar power system comprising a plurality of mounting supports (50), a plurality of photovoltaic modules (1) mounted on the mounting supports (50), a plurality of holding elements (60, 100) for holding the photovoltaic modules (1) on the mounting supports (50) and a plurality of electric connecting elements (60) for electrically interconnecting the photovoltaic modules, and wherein the electric connecting elements (60) comprise two electrically contacting connecting plugs (40-43, 70-74) which can be plugged together and which are designed such that they are plugged together with the mounting movement of the respective photovoltaic module when mounting it on a mounting support (50).

According to the invention the photovoltaic modules (1) are each bordered at the edge at least in sections by a holding frame (10) made of a plastic, wherein mechanical connecting means (30) and at least one connecting plug (40-43, 70-74) are integrated in the holding frame (10) and wherein the mechanical connecting means (30) each interact with an associated holding element (60, 100) in a positive fitting manner.

The present application claims the priorities of German patent applications DE 10 2005 050 884.7 “Photovoltaic Module, Method for its Production and System comprising a Plurality of Photovoltaic Modules”, filed on 21 Oct. 2005, and DE 10 2005 050 883.9 “Solar power system comprising a plurality of photovoltaic modules”, filed on 21 Oct. 2005, and their content is hereby expressly incorporated by reference into the present application.

### FIELD OF THE INVENTION

The present invention relates generally to photovoltaic modules with a holding frame, for example to be used to design roof coverings or facade surfaces and relates in particular to a solar power system comprising a plurality of photovoltaic modules.

### BACKGROUND OF THE INVENTION

Photovoltaic modules of the aforementioned kind convert radiation energy into electric energy. To satisfy the diverse requirement for the construction of solar systems, the solar cells are embedded in a mixture of numerous materials and components which is intended in particular to provide an electric connection option that meets practical requirements, to protect the non-corrosion-resistant solar cells from mechanical influences, to protect against the weather, to provide shock hazard protection for the electrically conductive components and for simplicity of handling and attachment. To enable photovoltaic modules to be used simply and flexibly, for example including by unskilled workers, this fast-growing technical field requires simple and robust mounting and connection concepts.

To enable sufficient mechanical support, it is known from the prior art, to accommodate a photovoltaic module in a mechanically stable frame made of aluminium or plastic and to provide between the frame and the laminate made of glass/solar cells/film composite a suitable sealing or soft-mounting material.

U.S. Pat. No. 5,578,142 or U.S. Pat. No. 6,172,295 B1 disclose a plastic frame profile for accommodating a photovoltaic module. Between the plastic frame and a sandwich structure comprising a transparent cover plate and solar cells, an adhesive layer or primer made of a plastic is applied by an injection moulding method. At a lower supporting limb of the holding frame, boreholes are provided for mounting the photovoltaic module. The sealing accommodation of the material composite of a transparent cover plate and solar cells in the holding frame is nevertheless relatively complex.

Therefore, to provide a simple frame holder, attempts have been made for a long time to produce the frame seal from a plastic which can be injection-moulded, foamed or cast in a suitable way onto the edge of a photovoltaic module. This approach is described generally, for example, in the German laid-open publication DE 28 32 475.

A further approach is described in U.S. Pat. No. 4,830,038 and the corresponding U.S. Pat. No. 5,008,062. A solar cell is introduced together with a transparent cover plate into an injection mould designed so that that injection moulding produces a frame encompassing the photovoltaic module. The material disclosed is in particular polyurethane. It is also possible simultaneously to integrate electric connecting means, namely plug-in connectors in the plastic frame by injection moulding. For the time after assembly, it is necessary to allow for forces, in particular caused by wind suction, the transmission of which to the mechanical connecting means can only be achieved by the plastic frame on its own with difficulty. Furthermore, the assembly of a photovoltaic module of this kind requires additional fastening elements. Therefore, a photovoltaic module of this kind is usually used in an aluminium or plastic frame which further increases the costs.

U.S. Pat. No. 5,743,970 discloses a further photovoltaic module, in which a polymer is injection-moulded onto the rear side of the solar cells in order to encapsulate the module. It also discloses that the plastic rear side can form suitable structures, for example a housing. Photovoltaic modules comprising a composite body are also disclosed in DE 198 14 652 A1, DE 198 14 653 A1 and DE 202 20 444 U1. Here, at least one layer comprises a polycarbonate and at least one further layer a fluorine-containing polymer.

To prevent output losses or even damage to the modules when they are in shadow and operated in the reverse direction, bypass diodes, typically based on silicon are used. Here, the bypass diodes and photovoltaic modules are combined with each other in an antiparallel configuration in such a way that the bypass diode is operated in the reverse direction when the assigned photovoltaic module is illuminated. Here, bypass diodes with very low reverse currents are preferred in order to prevent a reduction of the current in the photovoltaic module during its normal operation which would reduce the power efficiency.

According to the prior art, the bypass diodes are usually arranged in a connector outlet which is connected to a rear side of the photovoltaic module or applied directly thereto. Since the bypass diode is a component which induces losses, this inevitably causes the heating of the bypass diode and its immediate vicinity, including the solar cells, and this results in a certain reduction in efficiency when the light energy is converted into electric energy.

DE 103 93 214 T5 discloses a solar cell and a method for its manufacture with a bypass diode which is integrated in the semiconductor structure of the solar cells. Therefore, losses in the configuration of the bypass diode result in the heating of the solar cell arrangement and hence in reduced efficiency.

EP 768 720 B1 discloses a solar cell with an integrated bypass diode, with the bypass diode being arranged in a recess in the back side of the solar cell. Therefore, heating of the bypass diode leads directly to heating of the solar cells and reduced efficiency.

Despite high levels of research and development in this field, there is still need for improvement in order to provide a solar power system comprising a plurality of photovoltaic modules in which the photovoltaic modules can be electrically interconnected with relatively little effort and/or with design advantages.

DE 101 05 718 B4 discloses a solar power system according to the preamble of claim 1. U-shaped supporting profiles form a supporting structure into which the photovoltaic modules can be mounted vertically or obliquely suspended. Arranged on the rear side of the photovoltaic modules are suspension hooks which engage in the bolts of a supporting profile. Furthermore, connector plugs are provided on the rear side of the photovoltaic modules.

When the photovoltaic modules are suspended in the supporting profiles, during the assembly process, connecting plugs which can be plugged together are plugged together for the electric interconnection of the photovoltaic modules. A bypass diode can be accommodated in the plug-in members or in an associated connector outlet. However, particularly with a flat or inclined alignment of the photovoltaic modules, suspension of the photovoltaic modules in the supporting profiles is inexpedient. The force, with which the connecting plugs are plugged together cannot be exactly prespecified.

DE 41 40 683 A1 and DE 41 40 682 A1 disclose a solar power system, in which the photovoltaic modules comprise a holding frame made of a plastic with a connecting flange on all four sides with plugs embodied as depressions on their contact surface. The photovoltaic modules are connected by strips which partially cover the connecting flanges and have a contact pin arrangement that engages in the assigned plugs in an adjacent photovoltaic module. The strips are provided with through-holes which are penetrated by screws for connection to a roof or facade structure. However, the connecting flanges must have a certain width which results in lower system efficiency. The assembly of the systems is relatively complicated since the strips have to be screwed down tightly.

WO 99/63193 discloses a mounting device for photovoltaic modules, with the photovoltaic modules being held between two clamping elements. Provided to ensure stress-free holding of the photovoltaic modules are a coupling bell and a permanently elastic spring member in the form of an insert thus enabling a relative motion of the photovoltaic module relative to one of the clamping elements.

### SUMMARY OF THE INVENTION

The object of the present invention is to provide a solar power system which is simple to configure and to assemble comprising a plurality of photovoltaic modules, in which the photovoltaic modules can be electrically interconnected with relatively little effort and/or with design advantages.

This and further objects are achieved according to the present invention by a solar power system with the features according to claim 1. Further advantageous embodiments are the subject matter of the related claims.

Thus, the present invention is based on a solar power system comprising at least one mounting support and a plurality of photovoltaic modules which are mounted on the mounting support or supports and electrically interconnected in a suitable configuration and namely adapted both to electric requirements and to the structural conditions of a roof covering or facade on which the solar power system is mounted. Here, the mounting support can have a frame-like design with a plurality of fields provided in a matrix arrangement for the accommodation of a respective photovoltaic module. According to a further embodiment, profiles mounted parallel to each other on the roof covering or facade form the mounting support. Furthermore, the solar power system comprises a plurality of holding elements for holding the photovoltaic modules on the mounting supports and a plurality of connecting elements for the electrical interconnection of the photovoltaic modules.

According to the invention, the photovoltaic modules are each bordered at the edge at least in sections by a holding frame made of a plastic and more preferably of an elastomeric plastic, with mechanical connecting means and at least one connecting plug being integrated in the holding frame and the mechanical connecting means each interacting by positive fitting with an associated holding element.

The positive connection and the integration of both the mechanical connecting means and the connecting plugs in the plastic-holding frame enables according to the invention a precise and reliable attachment and electric interconnection of the photovoltaic modules. The holding frame can be produced by injection moulding or moulding tool-supported injection moulding according to the invention with very low tolerances. Therefore, the photovoltaic modules according to the invention can be aligned on and attached to the mounting supports without additional effort.

According to a further embodiment, the mechanical connecting means are detachably latched or interlocked to the holding elements. According to the invention, this enables the more precise specification of the retention forces which also determine the contact force for the establishment of the electric plug-in connection. Here, the latching or interlocking can specify a minimum force which is sufficient to achieve the electric plug-in connections for the interconnection of the photovoltaic modules. Furthermore, according to a further embodiment, suitable latching can achieve mechanical prestressing of the photovoltaic modules against the associated holding elements or mounting supports.

According to a further embodiment, bypass diodes are provided in or on the respective mounting support. This achieves a spatial separation from the solar cells so that heating of the bypass diodes does not directly result in the heating of the solar cells and hence to reduced photoelectric efficiency. The solar power system according to the present invention can therefore be operated more efficiently.

An arrangement of the bypass diodes in the mounting support can be achieved in a particular simple manner if the mounting support is embodied as a hollow profile, the hollow space of which can be easily accessed from outside. According to a preferred embodiment, the bypass diodes are each provided directly on the mounting support. For protection against environmental influences and to facilitate electric contacting, hereby, the bypass diodes are preferably accommodated in a separate housing provided with electric connectors or the like in each case said housing being arranged or mounted directly on the mounting support.

According to a first embodiment, this housing is embodied separately from the holding elements. According to a further embodiment, however, a housing of this kind can also simultaneously serve as a connecting or holding element which is mounted at a predetermined position corresponding to the electric interconnection of the photovoltaic modules on a mounting support so that the photovoltaic modules are held by the connecting elements.

Particularly preferably, here the mounting supports are designed in such a way that the connecting elements can here be attached to any points on the associated mounting supports and are in particular steplessly displaceable. According to a further embodiment, the connecting elements can be latched to predetermined points in the associated mounting supports. To this end, latching elements can be provided on the mounting support in a suitable grid dimension which is matched to the geometric dimensions of the photovoltaic modules to be accommodated into which latching element the connecting elements can each be latched. During assembly, therefore, it is only necessary to search for these latching points. It is, therefore, virtually impossible for the connecting elements to be mounted at incorrect distances which significantly increases the speed and reliability of assembly including by unskilled workers.

According to a further embodiment, the mounting supports are embodied as endless profiles, for example with a square or rectangular cross section. Here, the endless profiles can be embodied with at least one depression or groove extending in the longitudinal direction and/or with at least one projection extending in the longitudinal direction, into which correspondingly embodied latching means of the connecting elements engage. The longitudinal depression or protrusion can here be embodied with a suitable profile for securely holding the connecting elements, in particular as a T-groove.

With a matrix arrangement of photovoltaic modules, it may optionally be necessary for horizontally or vertically adjacent photovoltaic modules to be interconnected. To guarantee an interconnection of this kind, according to a further embodiment, the mechanical connecting means and/or the connecting plug or plugs are provided on opposing longitudinal sides of the rectangular or square photovoltaic module at identical positions in such a way that the photovoltaic modules can be optionally mounted in different rotational positions on the mounting supports in order to enable a suitable electric interconnection of the photovoltaic modules corresponding to their respective rotational position.

In particular, the mechanical connecting means and/or the connecting plug or plugs can be provided on opposing longitudinal sides of the rectangular or square photovoltaic module at identical positions in such a way that, in a first rotational position, an electric connection to a horizontal adjacent photovoltaic module can be established and, in a second, different rotational position, which is preferably rotated by 180° relative to the first rotational position, an electric connection to a vertically adjacent photovoltaic module can be established.

According to a further embodiment, an anchoring or retaining means can also be integrated in the plastic material of the holding frame in order to prevent the aforementioned connecting and/or aligning means being torn from or out of the holding frame, for example in the case of wind suction after assembly. An anchoring means of this kind can in particular be embodied as a profile integrated in the holding frame, said profile extending at least in sections in the circumferential direction of the holding frame and into which the connecting and/or aligning means engage in order to be retained on the holding frame.

According to a further embodiment, the solar power system further comprises at least one inverter module, which can also be claimed by an independent claim, with an external appearance identical to that of the photovoltaic modules and which is mounted at a suitable position in the arrangement of photovoltaic modules on the mounting support.

Therefore, this further aspect of the present invention relates in particular to an inverter module for a solar power system of the aforementioned type.

While inverter modules according to the prior art are usually provided at a distance from the arrangement of photovoltaic modules which necessitates the installation of a plurality of comparatively expensive DC lines, according to the invention, line routes between the inverter module and the photovoltaic modules are designed smaller and less expensively. Since, externally, the inverter module cannot be distinguished from the photovoltaic modules, it can be arranged at any position in the arrangement of photovoltaic modules so that the solar power system according to the invention can be adapted even more flexibly to electric requirements and structural conditions.

Preferably, therefore, the inverter module has an identical mechanical structure to that of the photovoltaic modules and in particular is mounted in an identical manner on the mounting supports, as described above.

According to a further embodiment, the inverter module here comprises in particular a cover plate which is colour-matched to the transparent cover plate with the underlying solar cell arrangement of a photovoltaic module provided with a rear side film or coating. Here, colour matching should be in particular be understood to mean an identical colour design or a colour design with little contrast so that the inverter module fits harmoniously into the arrangement of photovoltaic modules without being perceived as spoiling the appearance. For example, the inverter module could have a surface with a greyish sheen and/or the cover plate over the inverter module could have a surface with a slightly bluish sheen corresponding to the photovoltaic modules, while the cover plates over photovoltaic modules usually have a surface with a slightly bluish sheen, although this depends on the materials used for the solar cells.

A further aspect of the present invention further relates to a method for the assembly of a solar power system, as is described in more detail.

### OVERVIEW OF THE FIGURES

The invention will be described below by way of example with reference to the attached drawings from which further features, advantages and objects to be achieved may be derived, these show:

FIG. 1 a perspective exploded view of a detail of a solar power system according to a first embodiment of the present invention;

FIGS. 2a and 2b a perspective view of a holding element of the solar power system according to FIG. 1;

FIGS. 3a to 3c a top view, perspective top view and a side view of an electric connecting element of the solar power system according to FIG. 1;

FIGS. 4a to 4d a corner region of a holding frame of the solar power system according to FIG. 1 in a view from below, in a perspective top view, in a side view and a sectional view;

FIG. 5 a partial perspective exploded view of a mounting support embodied as an endless profile with a connecting element according to a second embodiment of the present invention;

FIG. 6 the system according to FIG. 5 in an assembled condition;

FIG. 7 a corresponding system according to a modification of the second embodiment of the present invention;

FIG. 8 a schematic partial section of a photovoltaic module with a connector plug integrated in the holding frame on the rear side and a corresponding connecting socket of an electric connecting element in a solar power system according to the present invention;

FIG. 9a an example of an electric string interconnection of an inverter module with fifteen photovoltaic modules on a square base area;

FIG. 9b a schematic top view of a photovoltaic module with connector plugs according to the present invention;

FIG. 9c a top view of an inverter module according to the present invention with connector plugs provided thereon;

FIG. 10 an example of an electric string interconnection of an inverter module with fifteen photovoltaic modules on a square base area according to a further embodiment of the present invention, with two different alternatively achievable embodiments of the inverter module being shown in a superposition;

FIG. 11 a top view of an inverter module in the embodiment according to FIG. 10 with connector plugs provided thereon;

FIG. 12 a schematic cross section of an inverter module according to the present invention;

FIG. 13 a perspective exploded view of a photovoltaic module according to the present invention;

FIG. 14 a schematic sectional view of the photovoltaic module according to FIG. 13 with a mechanical aligning and connecting means; and

FIGS. 15a- 15c individual steps of a method for the production of the photovoltaic module according to the present invention.

In the figures, identical reference numbers identify identical or substantially equivalent elements or element groups.

### DETAILED DESCRIPTION OF PREFERRED EXEMPLARY EMBODIMENTS

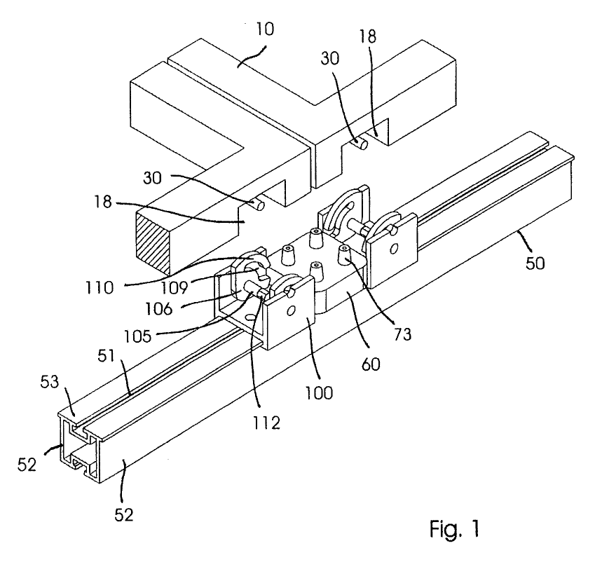

FIG. 1 shows in a perspective exploded view a detail of a solar power system according to a first embodiment of the present invention. This comprises a plurality of parallel mounting supports 50 arranged at a distance to each other or in a frame-like manner on which are mounted holding elements 100 and double bridges 60 serving as electric connecting elements. In each case, four holding elements 100 secure a photovoltaic module by positive fitting latching or interlocking of holding studs 30 disposed in the corner regions of the holding frame, as described below. On the interlocking of the holding studs 30, contact plugs or contact sockets arranged in corner regions on the underside of the holding frame are simultaneously plugged together with the associated contact sockets or contact plugs 73 of the double bridge 60 by means of which electric contacting for the interconnection of two adjacent photovoltaic modules is achieved.

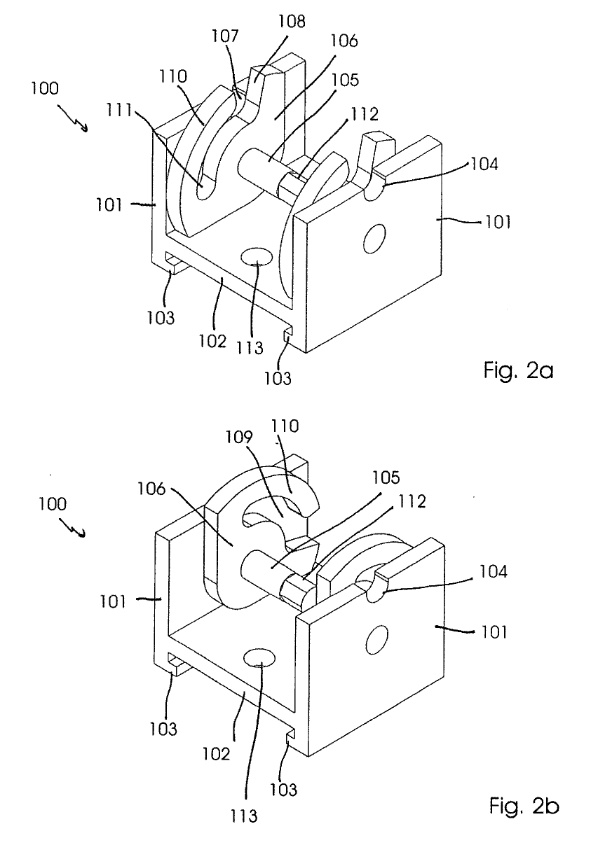

According to FIG. 1, the mounting support 50 is embodied as an endless profile with a square cross section, for example as an aluminium extruded profile. Embodied on the longitudinal sides of the mounting support 50 are two T-grooves 51, into which the correspondingly embodied latching elements engage, as described below. In the example of an embodiment according to FIG. 1, the upper profile limbs 53 protrude over the side walls 52 of the endless profile 50, which are encompassed by side walls 101 (see FIG. 2a) and transverse webs 103 of the holding elements 100. The holding elements 100 are therefore guided in a longitudinally displaceable manner by the mounting supports 50 in the manner of a guide rail, with the holding elements 100 being guided in a direction perpendicular to the longitudinal direction of the mounting supports 50 with a minimum clearance and perpendicularly upward with a minimum clearance or a clearance predetermined by the distance of the transverse webs 103 to the base 102 of the holding elements 100. According to FIG. 2a, embodied in the base 102, there is a borehole 113 into which a countersunk-head screw or a comparable fixing element with a profile element embodied correspondingly to the T-groove 51 of the mounting support 50, which engages in this to secure the longitudinal position of the holding element 100 and clamps the holding element 100 when the countersunk-head screw is tightened.

According to FIG. 2a and 2b, a claw formed by two curve elements 109 is mounted on a shaft 105 mounted on the side walls 101 of the holding element 100. This can be prestressed by means of a spring element or the like in the interlocking position shown in FIG. 2b. According to FIG. 2a, embodied in the curve elements 109 there is an eccentric circumferential groove 109 which opens outward via a lead-in opening 107 with a lead-in chamfer 108 for guiding the holding stud 30 of a photovoltaic module. Furthermore, embodied in the side walls 101 of the holding element 100 are two semicircular recesses 104 above the rotating shaft 105, each of which accommodate a holding stud 10 protruding perpendicularly from a side surface of the holding frame 10 for interlocking a photovoltaic module. In the rotational position of the claw according to FIG. 2a, the holding stud is disposed in the lead-in opening 107 of the eccentric groove 109. The lead-in chamfer 108 here guides the holding studs 30 reliably into the semicircular recess 104. The course of the eccentric groove 109 can optionally achieve a mechanical prestressing of the photovoltaic module against the holding element 100.

According to FIG. 1, a gap remains between two adjacent photovoltaic modules and the length of the rotating shaft 105 is greater by this gap width than twice the width of the holding frame 10 so that the hexagon insert bit 112 embodied on the external circumference of rotating shaft 105 can be actuated with a tool, for example a wrench, which engages in the gap in order to twist the rotating shaft 105 into the rotational position shown in FIG. 2b. Here, the holding stud 30 or the holding studs 30 are accommodated by two adjacent photovoltaic modules in the eccentric groove 109 and finally accommodated in a tightly fitting way in an accommodating element formed by a recess 104 and the base 111 of the groove 109. This secures the position of the photovoltaic modules in the longitudinal direction of the mounting supports 50 and in directions perpendicular thereto. An embodiment of the accommodating element of this kind is however, obviously, not imperative.

According to FIG. 1, the holding studs 30 are arranged in rectangular recesses 30 in corner regions of the holding frame 10 and do not protrude over the side surface of the holding frame 10. On the interlocking of the holding stud 30 in the holding element 100, here, the interlocking mechanism formed by the axially displaceable claw is accommodated in the recess 30. In interlocked position, the holding frames 10 are accommodated in a tightly fitting way by an accommodating element formed by the side walls 101 and the base 102 of the holding elements 100, which contributes to an increase in the torsional rigidity.

As will be evident to the person skilled in the art, the holding elements 100 are expediently injection-moulded or moulded from a plastic or produced from a metal material.

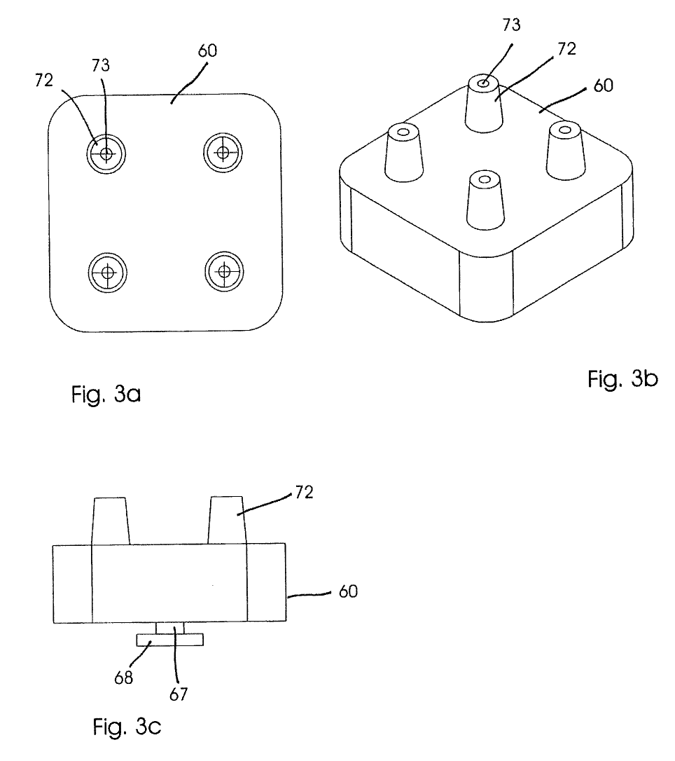

FIGS. 3a to 3c show the double bridge 60 for the electric interconnection of the photovoltaic modules. Arranged on the upper side of the double bridge 60 are four plug sockets 73 in a square arrangement. Embodied on the underside of the double bridge is profile element formed by a projection 67 and a transverse web 68, which profile element is formed in correspondence to the profile of the T-groove 51 (see FIG. 1) of the mounting supports 50 and engages therein. The longitudinal position of the double bridge located between two holding elements 100 on the mounting support 50 is automatically established on the securing of the holding elements 100. According to a further embodiment, the double bridge can be embodied in one piece with the holding elements 100 or connected to at least one holding element 100.

Depending on whether two vertically or horizontally adjacent photovoltaic modules are to be interconnected, two opposing contact sockets 73 of the double bridge are interconnected in the vertical or horizontal direction in the known manner. Provided in the double bridge 60 can be at least one bypass diode, which is operated in the reverse direction when the associated photovoltaic module is illuminated. As will be easily evident to the person skilled in the art, the housing of the double bridge is expediently injection-moulded from a plastic.

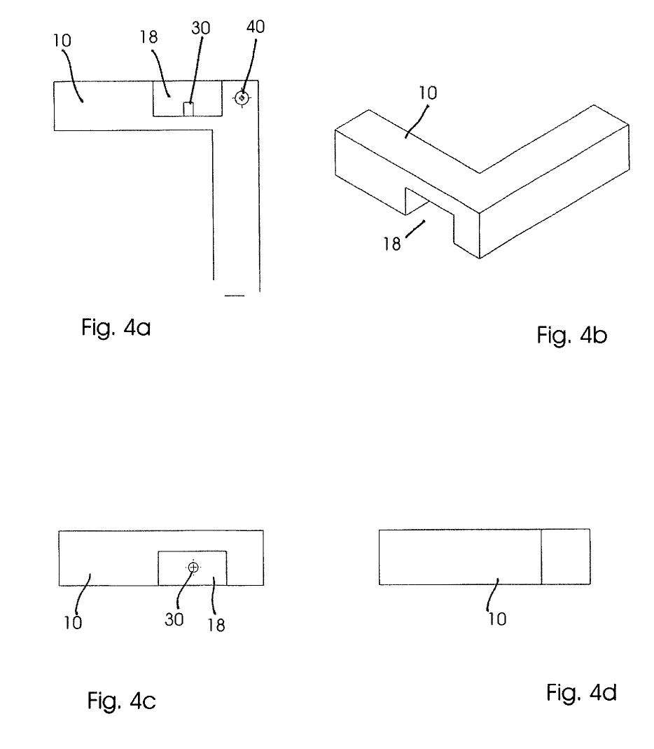

FIGS. 4a to 4d show a corner region of a holding frame 10 of a photovoltaic module in different views. According to FIG. 4a, integrated in the holding frame 10 is a perpendicularly upright contact plug 40, as will be described in more detail below. Arranged adjacent to the contact plugs 40 is the recess 30 with the holding stud 30 provided therein. The distance between the contact plug 40 and the holding stud 30 is here determined by the distance between the semicircular recess 104 (see FIG. 1) and the associated plug socket 73 on the upper side of the double bridge 60 when this lies directly on the holding element 100.

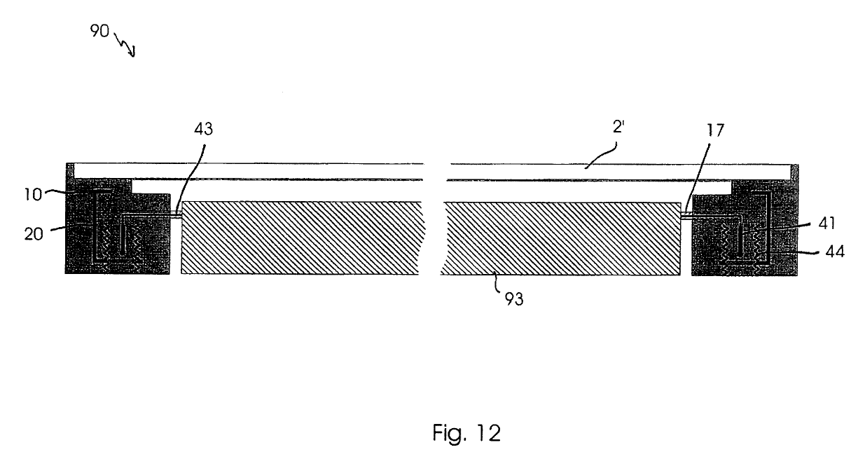

The method used to assemble the solar power system according to FIG. 1 is as follows: firstly, the mounting supports are fastened at prespecified distances, matched to the dimensions of the photovoltaic modules, on the roof or facade structure. Then, the holding elements 100 and double bridges 60 are inserted in the mounting supports 50 and brought into position. Then, the photovoltaic modules, optionally plus one or a plurality of inverter modules, as described below with reference to FIG. 12, are placed on the holding elements 100 and the double bridges 60 in the manner described above. In this position, the holding elements 100 can still be freely displaceable on the mounting supports 50. According to an alternative embodiment, however, in this phase, the holding elements 100 can already be firmly fixed on the mounting supports 50. Then, the position of the photovoltaic modules on the roof or facade structure is checked again and optionally corrected by displacement along the mounting supports 50. Then, the claws 109 of the holding elements 100 are turned by means of a tool, which engages in the gap between two adjacent photovoltaic modules, causing the photovoltaic modules to be firmly connected to the holding elements 100. Then, the position of the holding elements 100 on the mounting supports 50 is secured, for example by tightening the aforementioned countersunk-head screws. On the interlocking or latching of the photovoltaic modules on the holding elements 100, the modules are pressed with a force predetermined by the interlocking mechanism against the double bridges so that the connecting plugs are plugged together with a predetermined contact force.

As will be easily evident to the person skilled in the art, the holding elements 100 can be unlocked again at any time in order to release the photovoltaic modules again, or released on the mounting supports in order to correct the position of the holding elements 100 and photovoltaic modules. In order to reduce or prevent the introduction of stresses into the photovoltaic modules, for example caused by wind pressure or wind suction, snow loads, thermal stresses or the like, elastic compensation can be provided on the holding elements. For example, the rotating shafts 109 on the side walls 101 can be elastically mounted, the rotating shafts 109 and/or the side walls 101 can be made of an elastic material, the claws 109 can be made of an elastic material, the holding studs 30 in the holding frame can be made of an elastic material or elastically mounted thereon or a permanently elastic insert can be provided on the underside of the holding elements 100.

As will be easily evident to the person skilled in the art, to achieve a positive fitting connection for the attachment of the photovoltaic modules on the mounting supports on the holding frame of the photovoltaic modules, also other elements may be provided, which interact in the known manner with interlocking or latching mechanisms of the holding elements matched thereto.

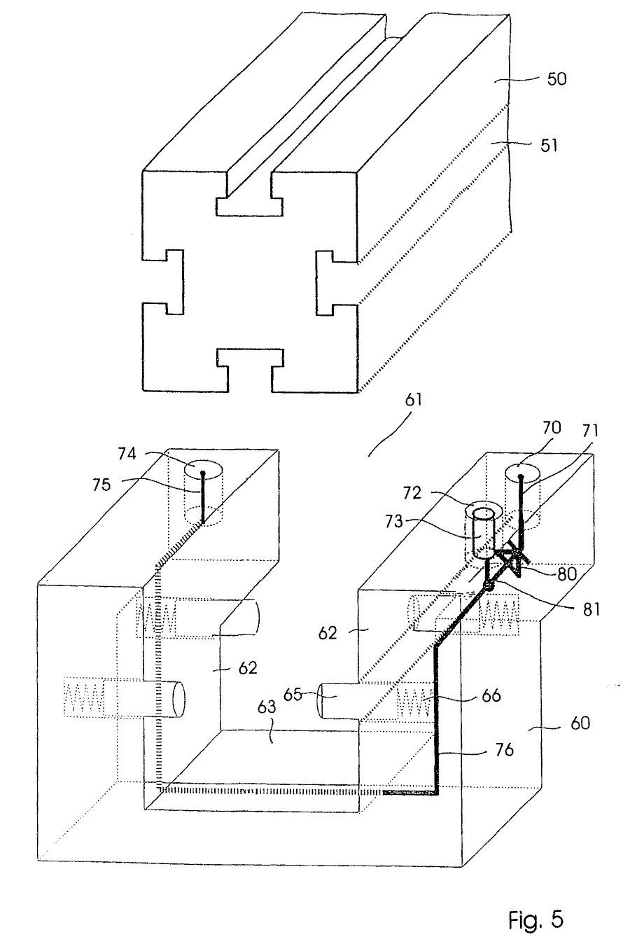

FIG. 5 shows a mounting support embodied as an endless profile with a connecting element according to a second embodiment of the present invention. According to FIG. 5, the mounting support 50 embodied as an endless profile is encompassed in a clamp-like manner by a connecting element 60 with a U-shaped cross section. In the middle of the connecting element 60, the two side walls 62 protruding perpendicularly from the base 63 form a central accommodating element 61 extending in the longitudinal direction for accommodating the mounting support 50 in the longitudinal direction. In assembled condition, the side walls 62 lie directly on side walls of the mounting support 50. Protruding from the side walls 62 are latching pins 65 which are prestressed inward by means of pressure springs. In assembled condition, the tips of the latching pins 65 protrude into the T-groove 51 of the associated mounting support 50 in order to latch the position of the connecting element 60 relative to the mounting support 50. Here, provided in the mounting supports 50, for example at the base of the T-grooves 51, there can be indexing blind holes which guide the latching pins 65 into a latched position. For the latching, the latching pins 65 are brought into engagement with the T-grooves 51 and the connecting element 60 pushed in the longitudinal direction along the mounting support 50 until the tips of the latching pins 65 engage in the indexing blind holes. The distances between these indexing blind holes are matched to the lengths or widths of the photovoltaic modules in such a way that these can be mounted in a tightly fitting way on the mounting supports, as will be described in more detail below.

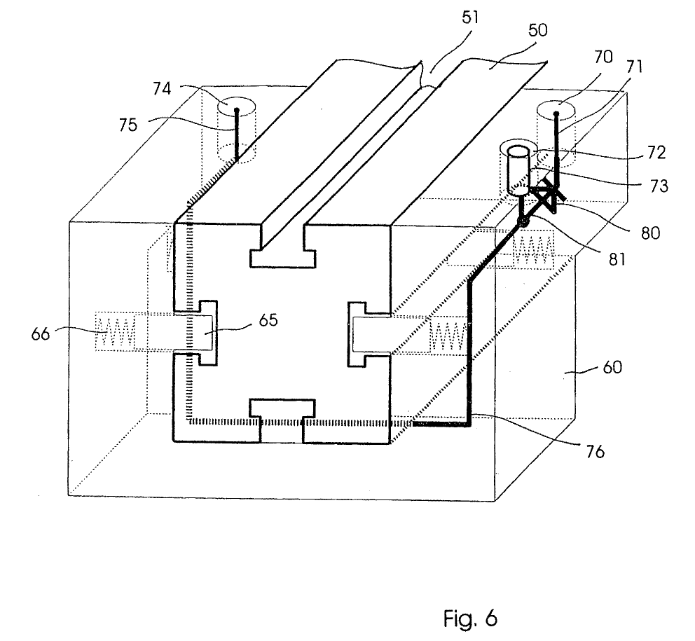

According to FIG. 5, provided on the upper side of the connecting element 60 on the left side of the mounting support 50 is a connector plug 74 with a contact pin 75 and arranged on the right side of the mounting support are a connector plug 70 with a contact pin 71 and an outlet 72 with a contact socket 73. The contact pin 71 and contact socket 73 are electrically conductively connected to each other by a connection line 81 with a bypass diode 80. The bypass diode 80 is switched so that it is operated in the reverse direction when the associated photovoltaic module plugged into connecting element 60 is illuminated and so that, when in shadow, the associated photovoltaic module is bridged by the bypass diode 80. According to FIG. 5, a further line 76 connects the connector outlet 72 to the connector plug 74 on the opposing side of the mounting support 50. FIG. 6 shows the system according to FIG. 5 in an assembled condition, in which the latching pins 65 protrude into the T-grooves 51 of the mounting support 50 in order to secure the connecting element 60 against being lifted off vertically.

The method for the assembly of a solar power system according to the second embodiment is as follows: firstly, as shown in FIG. 5, a plurality of mounting supports are mounted arranged parallel and at a distance from each other on a roof covering, facade or the like with the distances between the mounting supports corresponding to the length or width of the photovoltaic modules to be mounted. According to a further variant, further correspondingly formed mounting supports arranged parallel and at a distance to each other can be laid perpendicularly to the mounting supports mounted in this way with suitable recesses being provided on the crossing points on the profiles of the mounting supports.

Then, for every corner of the photovoltaic modules to be mounted, a connecting element 60 can be mounted, as shown in FIG. 5, at suitable positions along the length of the mounting supports, and namely in the example of an embodiment by latching the latching pins in the T-grooves of the mounting support. Here, the connecting elements can be arranged freely moving in the longitudinal direction along the mounting supports. According to a preferred embodiment, the connecting elements can only be attached at predetermined positions, corresponding to the lengths or widths of the photovoltaic modules to be mounted, on the mounting supports. To this end, alignment means, for example indexing blind holes, can be provided, as described above.

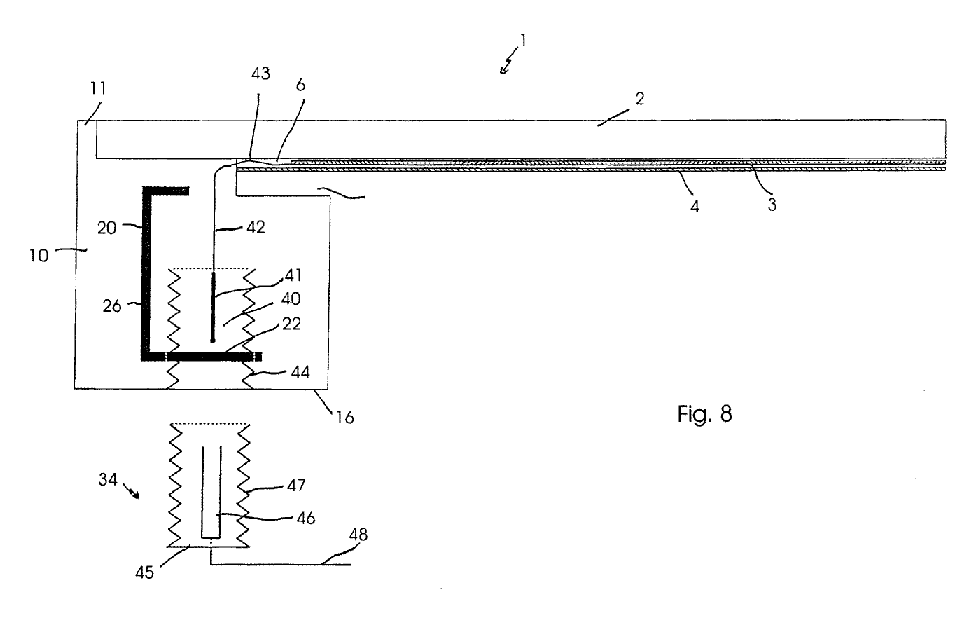

Then, as shown schematically in FIG. 8, the photovoltaic modules are placed on the connecting elements so that the connector plugs 40 and/or plug sockets provided on the underside of the holding frame 10 (see FIG. 4) engage with correspondingly embodied plug sockets and/or connector plugs provided on the upper side of the connecting elements 60 (see FIG. 5). This achieves electric contacting of the plugged-on photovoltaic module. The connection line 76 in the connecting element 60 here simultaneously achieves an electric connection with the photovoltaic module plugged-in on the opposing side of the mounting support 50. Transversely to the mounting support, therefore, opposing photovoltaic modules can be connected so in series with a bypass diode 80 being associated to the photovoltaic module arranged on the right-hand side according to FIG. 5, said diode being operated in the reverse direction, when the photovoltaic module on the right-hand side in FIG. 5 is illuminated and bridging this photovoltaic module when in shadow.

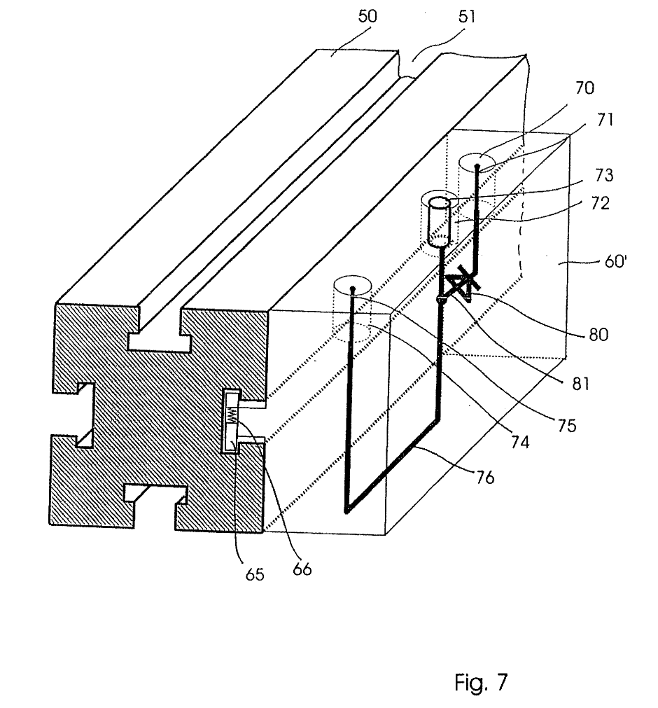

In order, to connect adjacent photovoltaic modules to each other in the longitudinal direction of the mounting supports in such a way that an associated photovoltaic module is bridged when in shadow, according to FIG. 7 a further type of connecting element 60′ is provided. In this connecting element, the connector plug 74 and the connector plug 70 with the associated plug socket 72 are disposed on the same side of the mounting support 50 and within the same connecting element 60′. The connector plug 70 and plug socket 72 are interconnected by a bypass diode and intended to accommodate a correspondingly formed socket and a correspondingly formed plug of a first photovoltaic module. The connection to the adjacent photovoltaic module in the longitudinal direction of the mounting support 50 is provided via the connection line 76 and the connector plug 74.

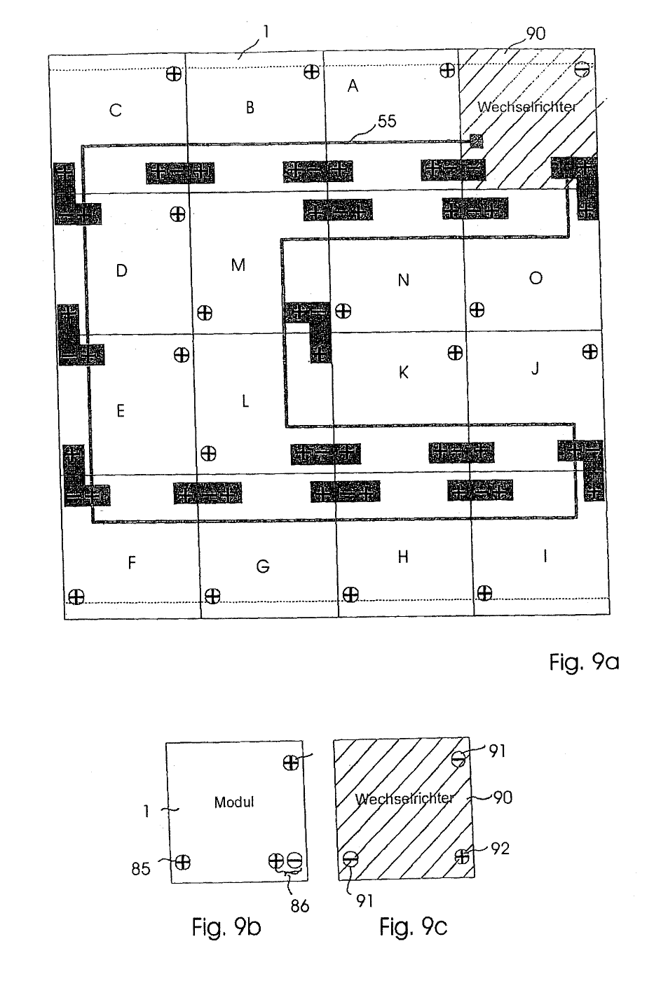

In this way, by means of a suitable geometrical arrangement of the two types of connecting elements on the mounting supports, it is possible to achieve a suitable electric interconnection of a plurality of photovoltaic modules, as shown by way of example in FIG. 9a. According to FIG. 9a, photovoltaic modules 1 designated with the letters A to O are connected in series in alphabetical order. Overall, the solar power system comprises fifteen photovoltaic modules 1 and an inverter module 90 with an external appearance which is substantially identical to that of the photovoltaic modules 1, in particular with a surface colour and design identical or matched to that of the adjacent photovoltaic modules.

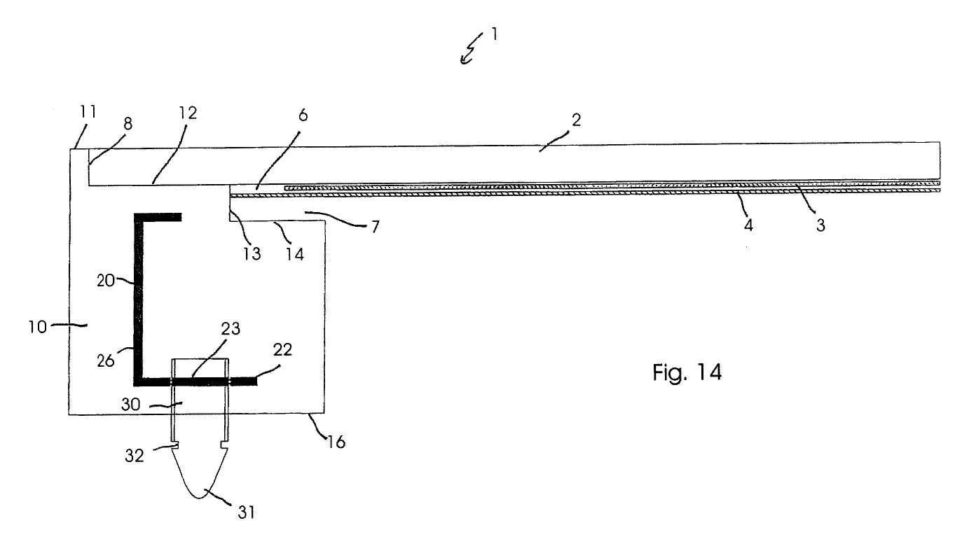

An inverter module 90 of this kind is shown by way of example in FIG. 12 in a sectional view. This inverter module 90 comprises a comparable mechanical structure to the photovoltaic module shown FIGS. 8 and 14 and described in more detail below. Instead of the solar cells, arranged on the rear side of the cover plate 2′ is the actual inverter 93, preferably encapsulated in a housing or a plastic. The remainder of the rear side of the cover plate 2′ can, as shown in FIG. 12, be coated with a plastic 17, which can in particular be embodied in one piece with the holding frame 10. The contacting of the inverter 93 takes place at the rear via the terminal lug 43 and the contact pin 41, in a way which will be described in further detail below in connection with the photovoltaic module according to FIG. 8.

The electric contacting of the photovoltaic module 1 is shown in FIG. 9b according to which there is a plus connection 85 in the top right corner of the module, a plus connection and a minus connection in the bottom right corner of the module and a plus connection 85 in the bottom left corner of the module. Here, the plugs are arranged on the underside of the holding frame of the module, as shown by way of example in FIG. 8. Here, the arrangement of the plug-in connectors is not mirror-symmetrical relative to the middle of the module 1. This enables in interaction with holding elements and corresponding double bridges, as described above in connection with the first embodiment, or with a corresponding first or second type of connecting element, as described above in connection with the second embodiment, in a first rotational position of the module 1, an interconnection with a horizontal adjacent photovoltaic module in FIG. 9a and, in a second rotational position, namely rotated by 180°, with a vertically adjacent photovoltaic module in FIG. 9a. The two rotational positions cannot be interchanged since the photovoltaic modules 1 and the inverter module 90 preferably have a rectangular basic shape and since connectors with an identical polarity are not arranged at identical positions along longitudinal sides of the holding frame.

According to FIG. 9a, the plus connection of a photovoltaic module is always connected to a minus connection of an adjacent photovoltaic module and namely via a connecting element, as shown in FIG. 6 or FIG. 7, with every photovoltaic module being associated to a bypass diode for protection, which according to the second embodiment is preferably integrated in the connecting element.

Since identical connecting elements are used for the connection of the inverter module 90, the inverter module 90 shown in FIG. 9c also has plug-in connectors 91, 92 at corresponding positions, although there is no need for a bypass diode.

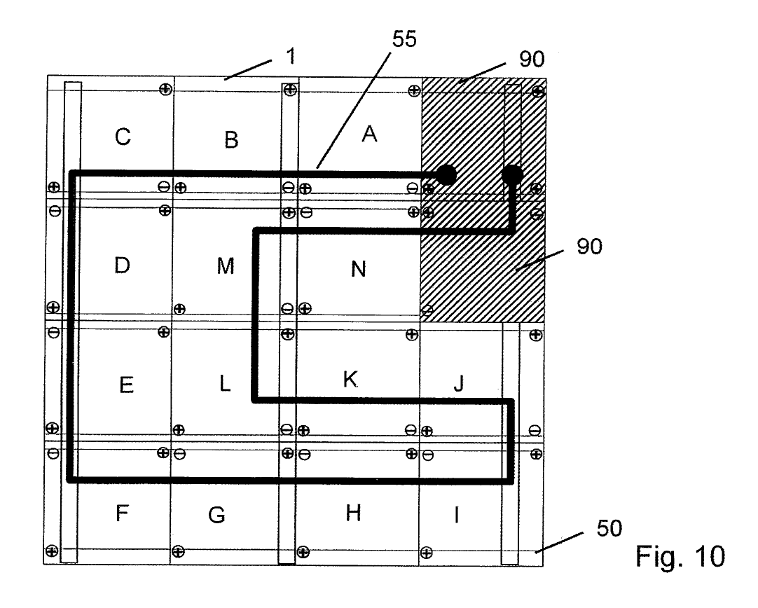

FIG. 10 shows an electric string interconnection of an inverter module with fifteen photovoltaic modules on a square base area according to a further embodiment of the present invention. The additionally shown second inverter module is to identify the optional position of the inverter module, in which case the first inverter module would be replaced by a photovoltaic module.

According to FIG. 10, respective plus connectors are provided in the top right and bottom left corner of the photovoltaic module 1 and a minus connector 85 is provided in the bottom right corner of the module. Here, the plugs are arranged on the underside of the holding frame of the module, as shown by way of example in FIG. 8. Here, the arrangement of the plug-in connectors is not mirror symmetrical relative to the middle of the module 1. This enables, in interaction with holding elements and corresponding double bridges, as described above in connection with the first embodiment, or, with a corresponding first or second type of connecting element, as described above in connection with the second embodiment, in a first rotational position of the module 1, an interconnection with a horizontal adjacent photovoltaic module in FIG. 10 and, in a second rotational position, namely rotated by 180°, with a vertically adjacent photovoltaic module in FIG. 10.

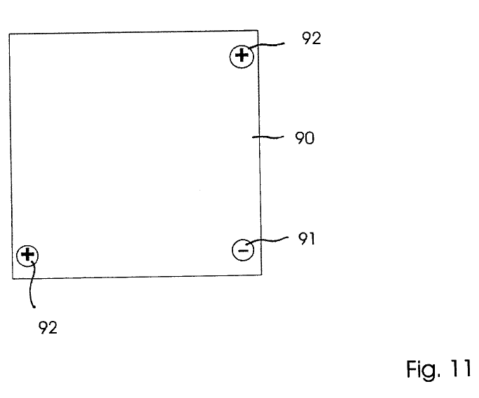

FIG. 11 shows an inverter module 90 designed for the interconnection according to FIG. 10 with a structure, as described above with reference to FIG. 12.

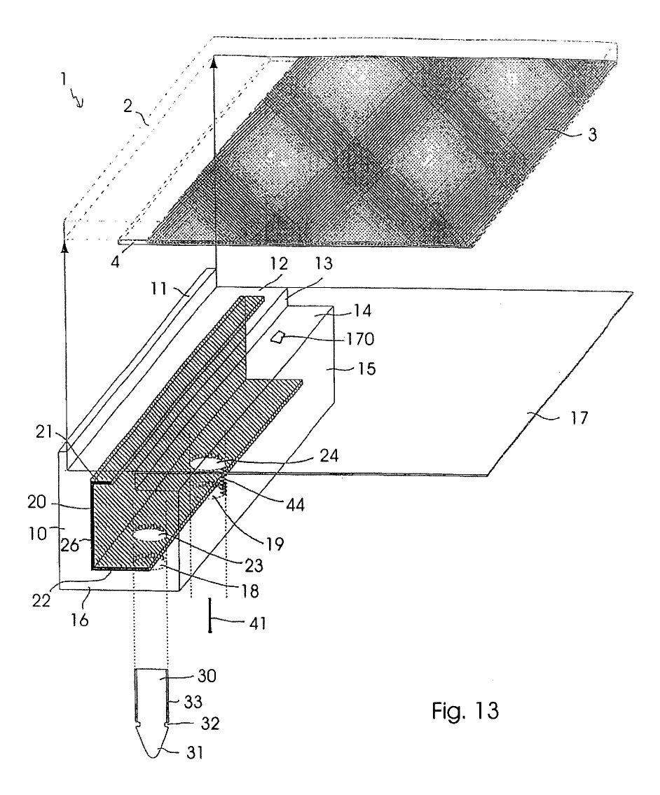

FIGS. 13 and 14 show, in a perspective exploded view and in a schematic partial section, a photovoltaic module for a solar power system according to the present invention.

According to FIG. 13, the photovoltaic module designated overall with the reference number 1 comprises a holding frame 10 with a substantially square profile, bearing a flat composite material which comprises a transparent cover plate 2, for example made of a glass or transparent plastic, and at least one solar cell 3, preferably a plurality of solar cells, with a transparent plastic layer, for example made of EVA, being provided, in which the solar cells 3 are embedded, between the cover plate 2 and the solar cells-arrangement. The rear side of the solar cells 3 can be clad with a weather-proof plastic composite film, for example made of polyvinyl fluoride and polyester. Alternatively, the solar cells can be cast in a synthetic resin and connected to the transparent cover plate 2. The solar cells 3 do not quite extend to the edge of transparent cover plate 2.

The holding frame 10 made of a plastic, for example polyurethane, is moulded-on, foamed-on or cast-on the edge of the aforementioned composite material and comprises a comparatively narrow upper circumferential edge 11, which borders the cover plate 2 at the edge at least in sections, optionally tightly all round, a horizontal supporting surface 12, the width of which is matched to the distance of the side edge of the encapsulation material 4 to the lateral edge of the transparent cover plate 2, a step 13, which is adjacent to an inner projection 14, which extends horizontally to the inner side of the photovoltaic module and an inner edge 15 and an underside 16, which is parallel to the supporting surface 12 and the inner projection 14. Between the rear side of the aforementioned composite material and the upper side of the inner projection 14, there remains a gap, the width of which is determined by the height of the step 13 and in a preferred example of an embodiment is, approximately 5.0 mm. Here, in a preferred example of an embodiment, the height of the inner edge 15 is approximately 30 mm. Overall, the holding frame 10 borders the material composite at the edge. According to FIG. 13, a plastic layer 17 is foamed or sprayed onto the rear side of the material composite, said layer preferably being made of the same material as the material of the holding frame 10, ie expediently of an elastomeric plastic. Overall, the arrangement of solar cells 3 is held in a hermetically sealed encapsulation in the holding frame 10.

According to a preferred embodiment (not shown), the upper edge of the holding frame 10 is flush with the transparent cover plate 2 of the photovoltaic module which provides the photovoltaic module with a more attractive appearance and results in comparatively low contamination with dirt and/or moss.

According to FIG. 13, integrated in the holding frame 10 there is a C-shaped profile 20 serving as an anchoring means, which comprises a lower limb 22 serving as a base, a vertical connecting limb 26 and a comparatively short upper limb 21, with the profile 20 being open toward the inner side of the photovoltaic module 1. The profile 20 extends in each case along the longitudinal sides of the photovoltaic module 1. Expediently, contiguous profiles 20 in the corners of the photovoltaic module are bevelled so that two adjacent profiles 20 can border each other directly. However, in principle, the profiles 20 can also have openings, including in the corner regions of the photovoltaic module.

According to FIG. 13, openings 23, 24 are arranged in the lower limb 22 at predetermined positions. As can be determined from viewing FIGS. 13 and 14 together, the shaft of a connecting pin 30 penetrates the opening 23, ie the connecting pin 30 engages in the profile 20. If the holding frame 10 is injection-moulded or foamed, the connecting pin 30 can be integrated therein. Alternatively, the connecting pin 30 can subsequently be connected to the holding frame 10, for example by screwing an external thread into the plastic of the holding frame 10 and/or into the profile 20. According to FIG. 13, the front end of the connecting pin 30 is provided with a conical tip 31, with a circumferential latch recess 32 being arranged in the transition region to the shaft for latching the connecting pin to a correspondingly embodied latch receiving element of a mounting frame (not shown).

As will be easily evident to the person skilled in the art, the connecting pin 30 can also protrude from a side surface of the holding frame 10 and be arranged in a recess embodied in the holding frame 10, as described above with reference to FIGS. 1 and 4.

As will be easily evident to the person skilled in the art, the aforementioned anchoring means can also be embodied as an enclosed hollow profile, which serves in the holding frame as a displacement body and so results in a further saving of plastic material. A hollow profile of this kind can also improve the rigidity of the holding frame overall.

As can be seen in FIGS. 13 and 8, arranged in the region of the opening 24 in the holding frame 10 is a cylindrical hollow space 40, with a contact pin 41 of a conventional electric plug arranged in the middle of its interior. Here, the contact pin 41 is here cast-in or foamed or cast-in in the plastic material of the holding frame 10. The contact pin 41 is connected to a wire 42 which extends vertically upward and here passes the upper limb 21 of the profile 20. Close to the rear side of the cover plate 2, the wire 42 is angled. The wire 42 passes over or is connected to a terminal lug 43, which penetrates the lateral edge of the composite material, in particular the encapsulation material 4 applied to the rear side in order to contact a solar cell 3 laterally in a suitable way. The profile 20 can also be made of a metal, for example as a conventional extruded profile.

According to FIG. 8, the circumferential wall of the hollow space 40 comprises a ribbing 44 or a comparable positive locking structure, which on the engagement of the above-described plug in a correspondingly embodied plug socket interacts with a correspondingly formed positive locking structure, for example a complementary ribbing 47, of the complementary plug socket in order to seal the electric plug-in connection. The mounting frame is designated schematically in FIG. 8 with the reference number 34 and comprises a plurality of mounting supports, as described above.

As indicated schematically in FIG. 8, a plug socket in the mounting frame 34 comprises a plug pin receptacle 46 arranged centrally in a socket 45, with the accommodating element 46 being connected to a electric connecting element, for example an electric connecting cable. The connecting element 48 is connected to an adjacent plug socket, with which an adjacent photovoltaic module or an adjacent inverter enters into an electric connection on insertion in the mounting frame. Hence, the mounting frame achieves a suitable interconnection of a plurality of photovoltaic modules and optionally at least one inverter. According to a particularly preferred embodiment, the above described mechanical connecting means and the above described electric connecting means are provided on opposing longitudinal sides of a photovoltaic module at identical positions. Here, the photovoltaic module can have a square or rectangular basic shape. In this configuration, the photovoltaic modules can be plugged into the mounting frame in different rotational positions, for example under 0°, 90°, 180° and 270°. In this way, a suitable choice of the rotational positions enables a suitable interconnection direction of the photovoltaic modules to be achieved, as described above with reference to FIGS. 9 and 10.

On the insertion of a photovoltaic module, the conical tips 31 of the connecting pins simultaneously also serve as aligning or guiding means in order to guide the photovoltaic modules into their suitable positions or align them there. This facilitates the simple and quick mounting of the photovoltaic modules according to the invention.

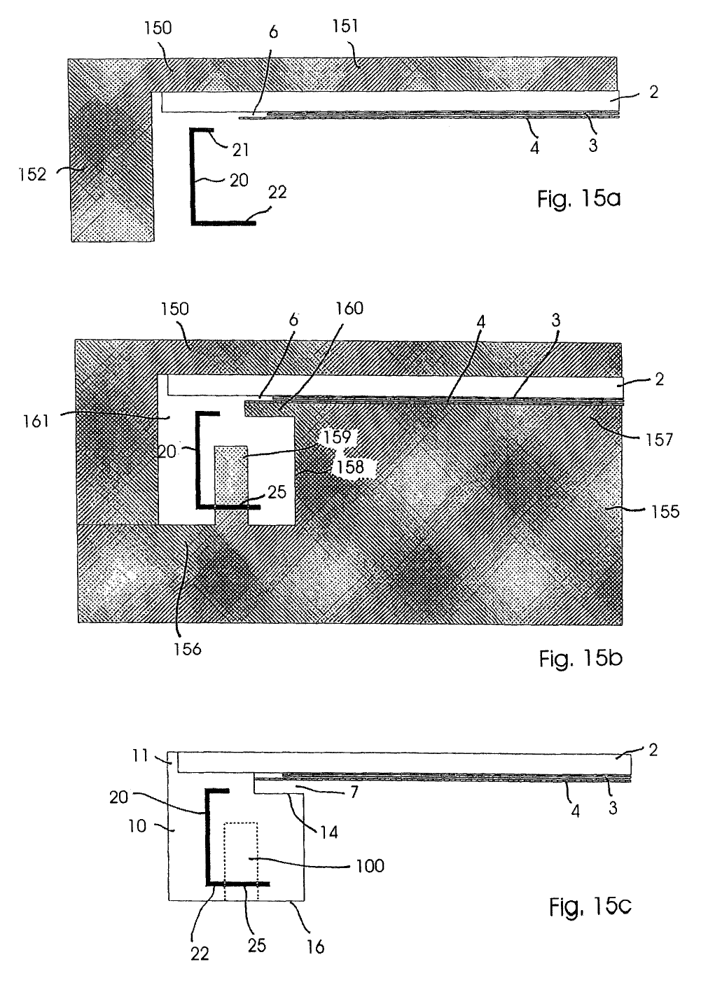

The following will explain, by way of example with reference to FIGS. 15a-15c, a method according to the present invention for the production of photovoltaic modules. According to FIG. 15a, the material composite comprising a transparent cover plate 2 and the solar cell arrangement 3 is placed on the base 51 of a trough-shaped mould 50 with side walls 52 protruding perpendicularly from the base so that the upper side of the cover plate 2 lies on the base 51. To produce the material composite, before this a cut-to-size web of EVA film can be placed on the rear side of the cover plate 2. The solar cells are, for example, previously connected by means of solder strips to form chains and positioned exactly on the plate with the EVA film. Then, the crosspieces, which connect the individual chains together, are positioned and soldered. Then, everything will be covered, for example in sequence, with a cut-to-size EVA film and a Tedlar® film. In the next stage of the process, the module is laminated at low pressure and approximately 150° Celsius. During the lamination, the up-to-then milky EVA film is converted into a clear, three-dimensionally crosslinked and no longer meltable plastic layer, in which the solar cells are embedded and which is firmly connected to the cover plate and rear side film. Alternatively, instead of the EVA film it is also possible to use a film made of thermoplastics such as thermoplastic polyurethane (TPU) or polyvinyl butyral (PVB) or the solar cells can also be cast-in in a known way and connected to the cover plate. Then, the semi-finished product produced in this way according to FIG. 15a is placed in a, for example, trough-shaped mould 50.

According to FIG. 15a, the C-shaped profiles 20 are arranged at a distance from the side walls 52 of the mould 50. To this end, vertically protruding projections 59 on the base 56 of a countermould 55 can be used as spacers for temporarily holding the profiles 20. According to FIG. 15b, the countermould 55 comprises a central, raised portion 57, which, in the case of a tightly closed mould, lies on the rear side of the aforementioned material composites. Hence, close to the side walls of the closed mould, a circumferential channel 61 with a substantially square cross section is formed, in which the profiles 20 are arranged at a distance from the inner circumferential walls of the channel 61. Protruding from the elevated portion 57, there is a projection 60 which serves to mould the gap 7 on the rear side of the photovoltaic module (see FIG. 15a).

According to FIG. 15b, between the lateral edge of the cover plate 2 and the side wall 52 of the mould 50, a gap is formed which determines the width of the upper circumferential edge 11 of the holding frame (see FIG. 15c).

The holding frame is formed by filling the circumferential channel 61 with a closed mould; the process conditions are sufficiently known per se from the prior art and do not need to be described in more detail here. By way of example, reference is made to the process conditions and materials disclosed in U.S. Pat. No. 4,830,038, U.S. Pat. No. 5,008,062, DE 198 14 652 A1, DE 198 14 653 A1 and DE 202 20 444 U1. The content of all the aforementioned publications for disclosure purposes is expressly included in the present application.

Finally, in this way, the holding frame 10 shown in cross section in FIG. 15c is formed, which borders the cover plate and the arrangement of solar cells 3 at the edge circumferentially and tightly. After the demoulding of the projection 59 (see FIG. 15b), a cylindrical hollow space 100 remains in the region of an opening 25 in the lower limb 22 of the profile 20, in which space for example a mechanical connecting means, as described above, can be accommodated.

As can be derived from FIG. 13, simultaneously further components can also be integrated in the holding frame (in FIG. 13 indicated by the reference number 170), for example a sensor, an electronic component, for example an inverter or a bypass diode, or an electronic circuit, for example a circuit with a bypass diode or free-wheeling diode or a circuit for wireless message transmission etc.

### LIST OF REFERENCE NUMBERS

1 Photovoltaic module
2, 2′ Transparent cover plate
3 Solar cell
4 Encapsulation material
7 Recess
8 Connecting edge
10 Holding frame
11 Circumferential edge
12 Supporting surface
13 Step
14 Inner projection
15 Inner edge
16 Underside
17 Rear plastic layer
18 Recess for mechanical connecting means
19 Recess for electric connecting means
20 Reinforcing means/C-profile
21 Upper limb
22 Lower limb
23 Opening for mechanical connecting means
24 Opening for electric connecting means
25 Opening for spacer 59
26 Vertical anchoring structure/connecting limb
30 Mechanical connecting and aligning element
31 Conical point
32 Latch recess
33 Thread
40 Connector plug
41 Contact pin
42 Electric connecting element/wire
43 Terminal lug
44 Positive locking structure
45 Socket
46 Plug pin receptacle
47 Positive locking element
48 Electric connecting element
50 profiles of the mounting frame
51 T-groove
52 Side wall
53 Upper profile limb
55 String interconnection
60 Terminal box/connecting element
61 Accommodating element
62 Side wall
63 Base
65 Latching means/latching pin
66 Spring
67 Projection
68 Transverse web
70 Connector plug
71 Contact pin
72 Connector outlet
73 Contact socket
74 Connector plug
75 Contact pin
76 Electrical connection
80 Bypass free-wheeling diode
81 Bypass line
85 Plus connection of the photovoltaic module
86 +/− connection of the photovoltaic module
90 Inverter module
91 Minus connection
92 Plus connection
93 Inverter
100 Fastening element
101 Side wall
102 Base
103 Transverse web
104 Centring recess
105 Rotating shaft
106 Rotary claw
107 Lead-in opening
108 Lead-in chamfer
109 Latching recess
110 Curved lateral web
111 Base of the latching recess
112 Hexagon insert bit portion
113 Borehole
150 Upper mould half
151 Base
152 Side wall
155 Lower mould half
156 Flat lateral edge
157 Central raised region
158 Step
159 Spacer
160 Circumferential projection
161 Hollow space
170 Electronic component/circuit
200 Hollow space

1. A solar power system comprising
a plurality of mounting supports,
a plurality of photovoltaic modules mounted on the mounting supports
a plurality of holding elements for holding the photovoltaic modules on the mounting supports and
a plurality of electric connecting elements for electrically interconnecting the photovoltaic modules, wherein:
said electric connecting elements comprise two electrically contacting connecting plugs which can be plugged together;
the photovoltaic modules are each bordered at the edge at least in sections by a holding frame, wherein mechanical connecting means are integrated in the holding frame; and
the holding elements are mounted onto the mounting supports;
wherein the holding frame is made of a plastic and at least one connecting plug is integrated in the holding frame, and wherein the mechanical connecting means are latched or interlocked to the holding elements in a detachable manner such that the connecting plugs are plugged together while the mechanical connecting means are latched or interlocked to the holding elements in order to electrically interconnect adjacent photovoltaic modules.

2. The solar power system as claimed in claim 1, wherein the holding elements are guided slidably in longitudinal direction and are secured by means of securing elements.

3. The solar power system as claimed in claim 1, wherein the mechanical connecting means are latched or interlocked to the holding elements in such a manner that the connecting plugs are plugged together with a predetermined minimum force.

4. The solar power system as claimed in claim 1, wherein the photovoltaic modules can be placed or plugged from above perpendicularly onto the holding elements arranged on the mounting supports and onto the electric connecting elements so that the connecting plugs are plugged together and the holding elements and the electric connecting elements are covered fully or with the exception of a narrow gap by the photovoltaic modules held by the holding elements in each case between two adjacent photovoltaic modules.

5. The solar power system as claimed in claim 1, wherein the holding elements comprise a latching or interlocking mechanism for the detachable latching or interlocking of the mechanical connecting means to the holding elements.

6. The solar power system as claimed in claim 5, wherein an actuating element for actuating the latching or interlocking mechanism protrudes over an edge of the holding frame so that the latching or interlocking mechanism can be actuated by a tool via the gap in each case between two adjacent photovoltaic modules in order optionally to latch or interlock or to release the associated mechanical connecting means.

7. The solar power system as claimed in claim 5, said latching or interlocking mechanism comprising at least one claw being rotationally supported on the holding element, which has an eccentric, circumferential recess for accommodating the associated mechanical connecting means and latches or interlocks it in a holding position on rotation.

8. The solar power system as claimed in claim 7, said holding elements further comprising at least one recess for accommodating the associated mechanical connecting means so that it is latched or interlocked in a predetermined position on the respective holding element.

9. The solar power system as claimed in claim 1, wherein the mechanical connecting means protrude preferably perpendicularly from an underside or from one or two side faces of the holding frame.

10. The solar power system as claimed in claim 9, wherein the mechanical connecting means are each disposed within a recess formed in the holding frame, in which the respective associated latching or interlocking mechanism is accommodated, with side walls of the holding elements forming a receptacle formed in correspondence to the holding frame portion to be accommodated.

11. The solar power system as claimed in claim 1, wherein the mounting supports are formed as endless profiles with at least one recess extending in the longitudinal direction or at least one projection extending in the longitudinal direction, into which a correspondingly formed positive fitting structure of the holding elements and/or electric connecting elements engage in a positive fitting manner in such a manner that they are displaceably guided on the mounting supports in the longitudinal direction and mounted in a direction perpendicularly thereto with a vanishing or predetermined clearance.

12-13. (canceled)

14. The solar power system as claimed in claim 1, wherein the holding elements and the electric connecting elements are embodied as separate elements, which can be arranged in a predetermined position relative to each other corresponding to the position of the mechanical connecting means and the connecting plugs on the holding frame on the mounting supports.

15. The solar power system as claimed in claim 14, wherein at least one bypass diode is provided in the electric connecting means, said diode being operated in the reverse direction when the associated photovoltaic module is illuminated.

16. The solar power system as claimed in claim 1 wherein the holding elements and the electric connecting elements are embodied in one piece as connecting elements provided with electric connecting plugs in order to hold the photovoltaic modules on the mounting supports and interconnect them electrically.

17. The solar power system as claimed in claim 16, wherein at least one bypass diode is provided in the electric connecting means, said diode being operated in the reverse direction when the associated photovoltaic module is illuminated.

18-31. (canceled)

32. The solar power system as claimed in claim 1, wherein the holding frame is formed flattened in regions without mechanical alignment and/or connecting means and electric connecting means or is provided with a recess extending in the circumferential direction, wherein the recess penetrates through the material of the holding frame in outward direction in order to form an opening for the rear ventilation of the at least one solar cell.

33. The solar power system as claimed in claim 1, wherein the mechanical connecting means and/or the or the connecting plug or plugs on opposing longitudinal sides of the rectangular or square-shaped photovoltaic module are provided at identical positions in such a way that the photovoltaic modules can be optionally mounted in different rotational positions on the mounting supports in order to enable a suitable electric interconnection of the photovoltaic modules in correspondence to their respective rotational position.

34. The solar power system as claimed in claim 33, wherein the mechanical connecting means and/or the connecting plug or plugs are provided on opposing longitudinal sides of the rectangular or square-shaped photovoltaic module at identical positions in such a way that, in a first rotational position, an electric connection to a horizontal adjacent photovoltaic module can be established and, in a second, different rotational position, which is preferably rotated 180° relative to the first rotational position, an electric connection to a vertically adjacent photovoltaic module can be established.

35. The solar power system as claimed in claim 1, wherein the holding frame is flush with a transparent cover plate forming a front side of the photovoltaic module.

36. The solar power system as claimed in claim 1, wherein further at least one bypass diode is cast or injection-moulded in the holding frame, said diode being operated in the reverse direction when the associated photovoltaic module is illuminated.

37. The solar power system as claimed in claim 1, further comprising an inverter module with an external appearance identical or adapted to that of the photovoltaic modules and mounted in an identical way on the mounting support or supports.

38. The solar power system as claimed in claim 37, wherein inverter module comprises a cover plate which is colour-matched to the transparent cover plate with the underlying solar cell arrangement of a photovoltaic module provided with a rear film, with an inverter being held on a rear side of the cover plate and a holding frame made of a preferably elastomeric plastic bordering the cover plate at the edge at least in sections and holding the cover plate.

39. The solar power system as claimed in claim 38, wherein a gap is formed between the transparent cover plate of the inverter module and an inverter in order to enable the waste heat from the inverter to be removed by air convection.

40. The solar power system as claimed in claim 1, wherein the holding elements comprise elastic compensation means in order to reduce the introduction of stresses into the photovoltaic modules.

41. The solar power system as claimed in claim 5, wherein the latching or interlocking mechanism is further configured to prestress the photovoltaic module or the associated mechanical connecting means in a holding position against the holding element or the mounting supports.
